(19) United States
(12) Patent Application Publication
(10) Pub. No.: US 2015/0257288 A1
(43) Pub. Date: Sep. 10, 2015

(54) Support Assembly for a Portable Electronic Device

(71) Applicant: Paul Andrew Livernois, Clearwater, FL (US)

(72) Inventor: Paul Andrew Livernois, Clearwater, FL (US)

(21) Appl. No.: 14/195,879

(22) Filed: Mar. 4, 2014

(51) Int. Cl. H05K 5/02; F16M 11/38

(52) U.S. Cl. CPC H05K 5/0204; F16M 11/38

(57) ABSTRACT

A support assembly attachable to and providing a stand and hand grip member for a portable electronic device consisting of a pair of spaced apart rotatable rings mounted on a base, each having a mutually engageable linear portion capable of providing, individually or in combination, a prop or resting surface for the device in a variety of positions as well as a loop through which a finger may be passed to assist in the gripping of the device and finally a clip function engineered in the larger ring for mounting a device to belt loop, purse strap, or the like.

### BACKGROUND OF THE INVENTION

1. Field of the Invention

The invention resides in the field of accessories for portable electronic devices and more particularly relates to apparatus which provides a means for supporting the device in an upright position on a surface as well as a finger loop to assist in securely gripping the device as well as an apparatus that functions as a clip to allow the user to secure their device to a belt loop or purse strap.

2. Description of the Prior Art

The advent of personal portable electronic devices such as cell phones, tablets, MP3 players and the like has created a need to support these devices in an upright position on a surface as well as to securely grip them in the hand to prevent dropping and resultant damage. It is also desirable for consumers to have a device that allows them to clip their portable devices to their belt loop, purse strap or to a hook mounted in their automobile. A number of prior art examples disclosing varying arrangements to satisfy one or the other but not all three of these requirements exist in the prior art.

Typical of the support arrangements are easel style configurations attached to the back of the device which fold out to form a stand in conjunction with the device case itself. Additionally known are grip augmenting configurations consisting of flexible finger receiving tubes or sleeves, again attached to the back. These provide for hand held use of the device while ensuring a firm connection to the hand.

In contrast to the prior art, the present invention is an integrated apparatus for achieving both of these functions without adding or duplicating components or structural complexity as well as offering a third function as a clip.

### SUMMARY OF THE INVENTION

The invention may be summarized as a support assembly attachable to and providing a stand and hand grip member for a portable electronic device consisting of a pair of spaced apart rotatable rings mounted on a base, each having a mutually engageable linear portion capable of providing, individually or in combination, a prop or resting surface for the device in a variety of positions as well as a loop through which a finger may be passed to assist in the gripping of the device, the larger of the ring doubling as a clip which allows the user to clip or mount their device to various objects.

The rings are rotationally mounted such that each ring is capable of a wide range of rotation up to one hundred eighty degrees in relation to the base surface. The rings are sized one smaller than the other arranged to fit one inside the other when rotated flat, i.e., folded down against the base surface. The rotational configuration may also include means to intermittently lock the rings in a selected position, for example, an upright position, with respect to the base.

Additionally, the base may be further mounted on an intermediary sub-base that is in turn attached to the device, for example, mounted on the rear surface of the device. In this embodiment, the base is configured to rotate in relation to the sub-base about an axis perpendicular to the surface of the base and each is provided with a mutually cooperating intermittently locking arrangement which in combination allows the entire assembly to be fixed in a full range of angular orientations with respect to the case of the device.

These and other features and advantages of the invention will be come more clear from the following description of the preferred embodiment taken with the drawings which follows.

### DESCRIPTION OF THE DRAWINGS

FIGS. 1a and 1b are perspective views illustrating the preferred embodiment of the invention in use;

FIG. 2 is a perspective view of the preferred embodiment of the invention;

FIG. 3 is a top view of the preferred embodiment of the invention;

FIG. 4 is an exploded perspective view of the preferred embodiment of the invention;

FIG. 5 is a bottom view of one component of the preferred embodiment of the invention;

FIG. 6 is a perspective view of another component of the preferred embodiment of the invention;

FIG. 7 is a perspective view of an additional component of the preferred embodiment of the invention;

FIG. 8 is a top view of the component of FIG. 7; and

FIG. 9 is an additional perspective view of the preferred embodiment of the invention.

### DESCRIPTION OF THE PREFERRED EMBODIMENT

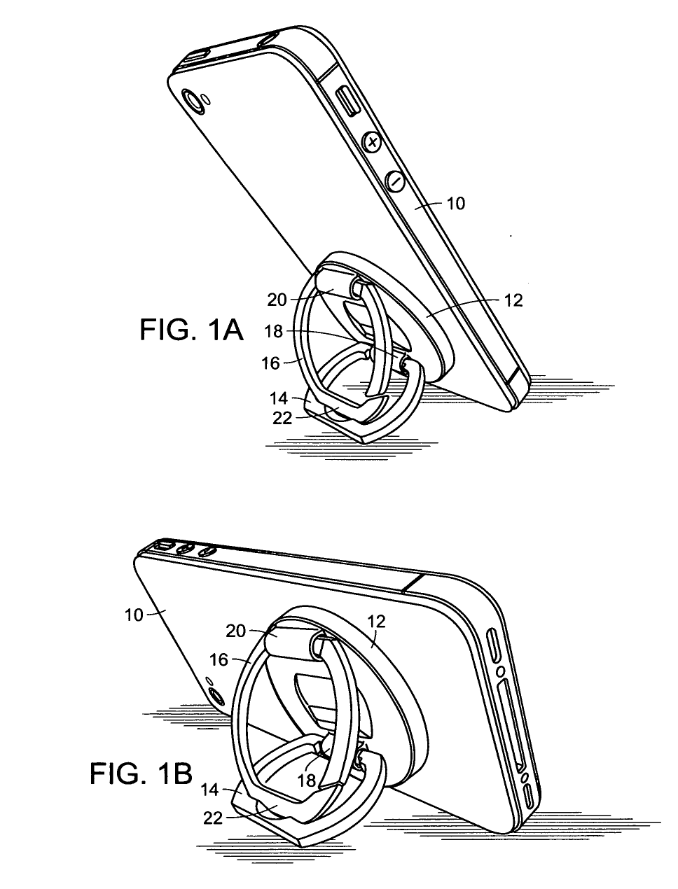

Referring to FIGS. 1a and 1b, representative examples of the invention in use are shown in which a personal electronic device 10, a cell phone for example, is supported vertically FIG. 1a, and horizontally FIG. 1b. The invention comprises a base 12 and two rings, a first smaller ring 14 and a second larger ring 16, both rotationally mounted on base 12 within sleeves 18 and 20 respectively. Each ring has opposed linear segments to be described in more detail below. The rings are configured to engage one another by, for example, the arrangement shown generally at 22.

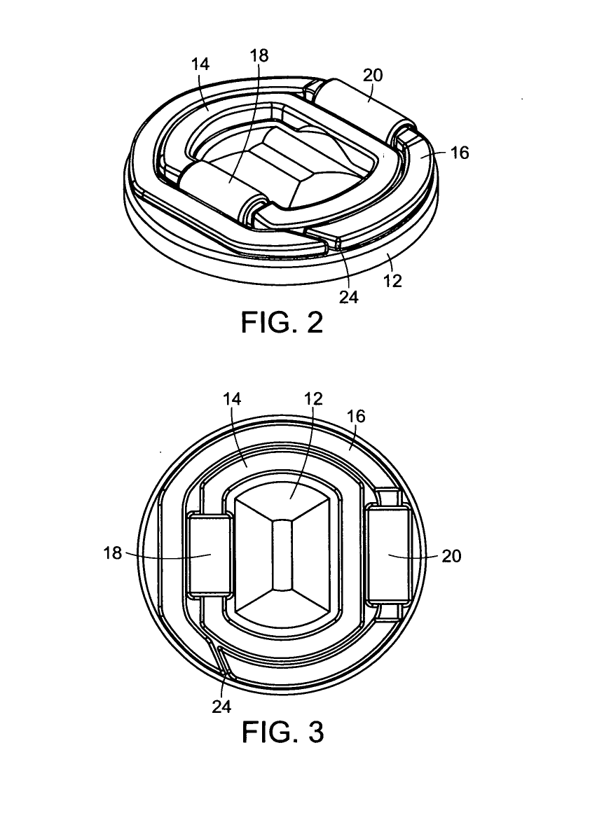

FIG. 2 is a perspective view of the invention separated from cell phone 10 showing, as well as in FIG. 3, rings 14 and 16 folded down against base 12 additionally illustrating a slit 24 in ring 16 which allows the ring to be passed over a belt, purse strap, or the like as a carrying arrangement. Also shown is the manner in which the rings are designed to lie flat against the base by sizing the larger ring 16 to fit over the smaller ring 14.

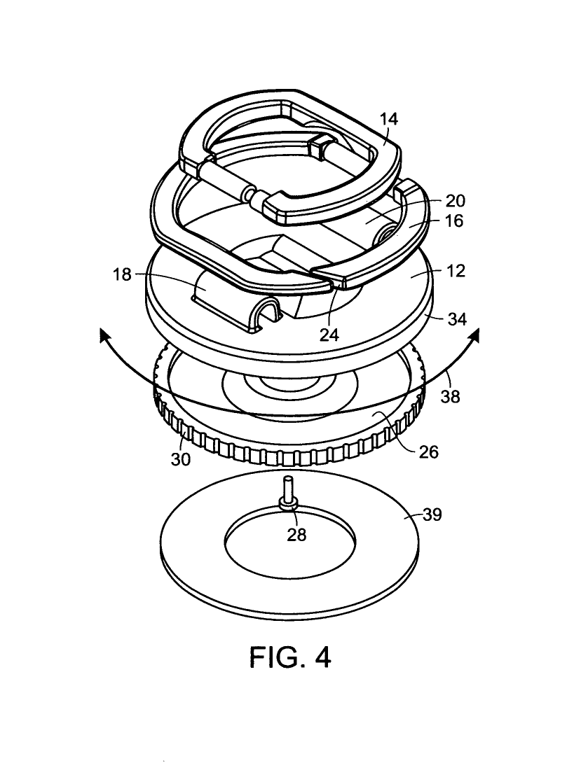

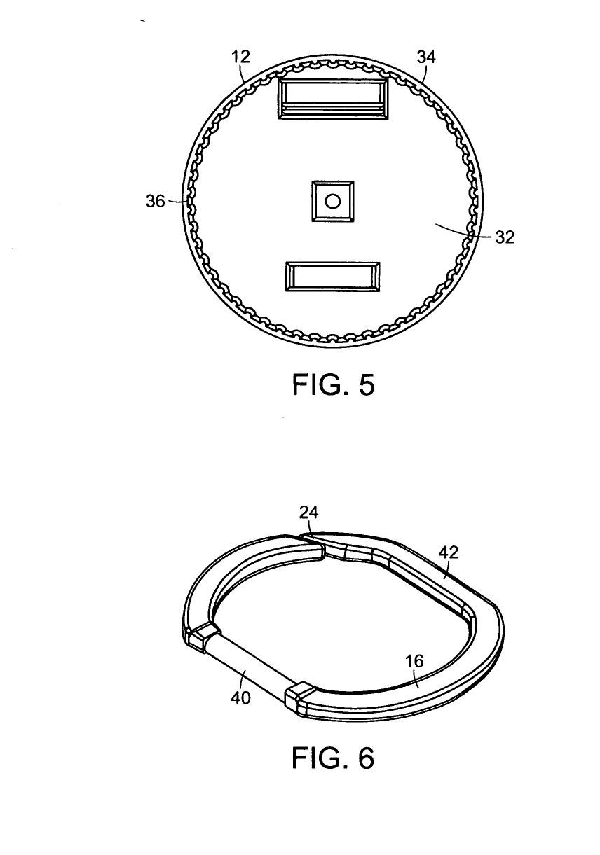

FIG. 4 is a perspective exploded view of the invention further illustrating an additional feature which may be incorporated into the basic device heretofore described. A sub-base 26 is added, mounted below base 12 and held in place by, for example, screw 28 and a washer not shown. In this embodiment, sub-base 26 has external teeth 30 disposed about the periphery or edge. Base 12 has a cavity 32 positioned on its underside and formed by rim 34. Teeth 36, which mesh with those of the sub-base, are located on the inside of rim 34 as shown in FIG. 5.

Both the base and the sub-base may be formed of a semi-flexible material such as hard plastic or soft metals and the configuration of the teeth are such that when the sub-base is disposed in cavity 32, flexing or deflection of the upper edges of the teeth is sufficient to allow mutual rotation of the base and sub-base while simultaneously locking the two together in any of the positions in which the teeth mate or mesh. This feature allows the base and ring assembly to be reoriented with respect to the electronic device in any number of positions, as indicated by arrow 38, when used as a stand or finger engaging and gripping mechanism.

Further shown in FIG. 4 is a sheet of adhesive 39 comprised of, for example, sticky polyurethane gel which will bind either the base or the sub-base to the electronic device depending on which embodiment is chosen.

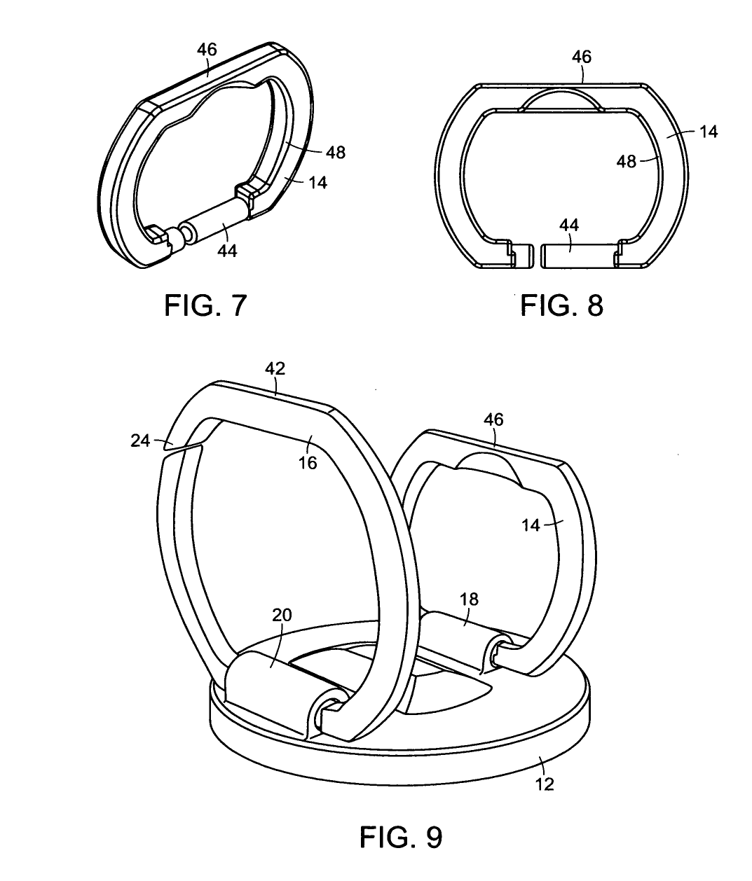

FIGS. 6-9 relate to structural details of rings 14 and 16. As shown in FIG. 6, ring 16 has two linear segments 40 and 42, segment 40 arranged to fit within sleeve 20. As an example of the way the ring can be held in a selected position in relation to base 12 as shown in FIG. 9, segment 40 is rectangular or square and bends or deforms sleeve 20 away from the base upon rotation of the ring. The ring then locks in between the upper surface of sleeve 20 and the base as the greater diameter of segment 20 is passed and the lesser diameter is reached.

The same arrangement is used for the smaller ring 14 having linear segments 44 and 46, segment 44 fitting into sleeve 18. Additionally the smaller ring may have an inner recess 48 which is sized to receive the outer edge of ring segment 42 as shown in FIGS. 1a and 1b.

The invention is accordingly defined by the following claims.

What is claimed is:

1. A support assembly attachable to and providing a stand and hand grip member for a portable electronic device comprising in combination:
A. a base;
B. a first ring rotationally attached to said base rotatable about a first axis, said first ring having a first ring linear portion spaced apart from and parallel to said first axis;
C. a second ring rotationally attached to said base rotatable about a second axis spaced apart from and parallel to said first axis, said second ring having a second ring linear portion spaced apart from and parallel to said second axis,
said first ring linear portion arranged to engage said second ring linear portion upon selective rotation of each of said rings,
at least one of said first and second rings having an inside diameter sufficient to receive a human finger; and
D. base attachment means to attach said base to said portable electronic device.

2. The support assembly of claim 1 further including means to limit the freedom of rotation of at least one of said rings.

3. The support assembly of claim 1 wherein said base attachment means comprises a sheet of adhesive.

4. The support assembly of claim 3 wherein said adhesive further comprises sticky polyurethane gel.

5. A support assembly attachable to and providing a stand and hand grip member for a portable electronic device comprising in combination:
A. a base having an outer side and an inner side;
B. a first ring rotationally attached to said base outer side rotatable about a first axis, said first ring having a first ring linear portion spaced apart from and parallel to first axis;
C. a second ring rotationally attached to said base outer side rotatable about a second axis spaced apart from and parallel to said first axis, said second ring having a second ring linear portion spaced apart from and parallel to said second axis,
said first ring linear portion arranged to engage said second ring linear portion upon selective rotation of each of said rings,
at least one of said first and second rings having an inside diameter sufficient to receive a human finger;
D. a sub-base rotationally mounted on the inner side of said base;
E. base locking means to secure said base and said sub-base together in a selected rotational position; and
F. sub-base attachment means to attach said sub-base to said portable electronic device.

6. The support assembly of claim 5 wherein said base locking means further comprises:
A. a plurality of teeth uniformly disposed about the parameter of said sub-base; and
B. a cavity disposed in said base for receiving said sub-base, said cavity having a plurality of teeth about its inner periphery meshing with those of said sub-base whereby upon mutual rotation of said base and said sub-base, a selected locked position is obtained from the mutual interaction of said teeth.

7. The support assembly of claim 6 further including means to limit the freedom of rotation of at least one of said rings.

8. The support assembly of claim 6 wherein said sub-base attachment means comprises a sheet of adhesive.

9. The support assembly of claim 8 wherein said adhesive further comprises sticky polyurethane gel.

10. The support assembly of claim 1 wherein one of said rings has a slit providing access to the interior of said ring for receiving a strap.

11. The support assembly of claim 5 wherein one of said rings has a slit providing access to the interior of said ring for receiving a strap.
